(19) United States
(12) Patent Application Publication
(10) Pub. No.: US 2025/0323495 A1
(43) Pub. Date: Oct. 16, 2025

(54) Techniques For Providing Electrostatic Discharge Protection Using An Off-Chip Capacitor

(71) Applicant: Altera Corporation, San Jose, CA (US)

(72) Inventors: Guang Chen, Fremont, CA (US); Archanna Srinivasan, San Jose, CA (US); Maneesha Yellepeddi, Los Gatos, CA (US); Anish Kumar, Chandler, AZ (US); Wai Ting Chong, Bayan Lepas (MY)

(73) Assignee: Altera Corporation, San Jose, CA (US)

(21) Appl. No.: 19/249,721

(22) Filed: Jun. 25, 2025

(51) Int. Cl. H02H 9/00; H02H 7/00; H02H 9/02

(52) U.S. Cl. CPC H02H 9/005; H02H 7/008; H02H 9/02

(57) ABSTRACT

A circuit system includes an electronic device having a first external terminal, a second external terminal, a third external terminal, and a power supply rail coupled to the first external terminal, the second external terminal, and the third external terminal. The circuit system also includes a capacitor coupled to the power supply rail in the electronic device through the third external terminal of the electronic device. The capacitor is configured to provide voltage overshoot protection to an integrated circuit die coupled to the first external terminal during an electrostatic discharge event occurring in the power supply rail. The capacitor is external to the integrated circuit die.

### BACKGROUND

An electrostatic discharge (ESD) event is a sudden flow of electricity between two circuits that is caused by contact, an electrical short, or breakdown. An ESD event can occur at an external terminal of an integrated circuit when the integrated circuit is handled by a person or machine. An ESD event can cause damage to, and possibly the failure of, an integrated circuit. An integrated circuit that contains field-effect transistors (FETs) having thin gate oxide regions cannot tolerate high gate voltages. If the integrated circuit experiences a high voltage ESD event at one of its input terminals, the field-effect transistors in the input buffer coupled to that input pin may experience breakdown.

### BRIEF DESCRIPTION OF DRAWINGS

FIG. 1 is a diagram that illustrates an example of a circuit system that includes an off-chip capacitor that provides electrostatic discharge (ESD) protection to an integrated circuit (IC) die in the circuit system.

FIG. 2 is a diagram that illustrates an example of an integrated circuit (IC) package that includes a capacitor in an interposer that provides electrostatic discharge (ESD) protection to an integrated circuit (IC) die in the IC package.

FIG. 3 is a schematic diagram that illustrates an example of a portion of a power supply rail in a substrate that provides power to an integrated circuit (IC) die.

FIG. 4 is a diagram that illustrates an example of a circuit system that includes a power supply rail for providing power to an IC die in the circuit system.

FIG. 5 is a diagram that illustrates an example of a configurable logic integrated circuit (IC).

FIG. 6A is a block diagram of a system that can be used to implement a circuit design to be programmed into a programmable logic device using design software.

FIG. 6B is a diagram that depicts an example of a programmable logic device that includes three fabric die and two base die that are connected to one another via microbumps.

FIG. 7 is a block diagram illustrating a computing system configured to implement one or more aspects of the embodiments disclosed herein.

### DETAILED DESCRIPTION

An electrostatic discharge (ESD) event can occur at an external terminal of an integrated circuit (IC) die during handling of the IC die before the IC die has been plugged into a power source. Previously known techniques for protecting integrated circuit (IC) dies from ESD events typically include on-die parts. For example, on-die diodes and clamps are used to satisfy a charge device model (CDM) specification of 250 volts and a high-bandwidth memory (HBM) specification of 1 kilovolt (kV) to meet ESD requirements for some IC dies. Some integrated circuit (IC) devices require low leakage current (e.g., about 200 nanoamperes (nA)) for battery powered rails and other rails that consume a small amount of electrical current. Many diodes that are used for ESD protection have a high leakage current. The IC die area that is required for an on-die ESD capacitor to meet a target for 250 megahertz (MHz) signal frequency may exceed the available space on the IC die. In addition, the large resistance of some types of on-die capacitors may cause a significant capacity reduction at 250 MHz.

According to some examples disclosed herein, a circuit system, such as an integrated circuit (IC) package, includes an off-chip capacitor that provides protection from electrostatic discharge (ESD) events (also referred to herein as ESD protection). The off-chip capacitor provides ESD protection to an integrated circuit (IC) die in the circuit system. The off-chip capacitor is outside of the IC die that the off-chip capacitor provides ESD protection for. The off-chip capacitor is coupled to a power supply rail that provides power to the IC die. The off-chip capacitor absorbs ESD charge injected from outside the circuit system to the power supply rail, and as a result, the off-chip capacitor protects the power supply rail and the IC die from damage caused by excessive voltage overshoot during an ESD event. The off-chip capacitor is located in the same circuit system (e.g., the same IC package) as the power supply rails that provide power supply to the IC die. The off-chip capacitor provides primary ESD protection for the IC die according to a resistor-inductor-capacitor (RLC) model. In some examples, there are no diodes or clamps in the IC die that provide ESD protection on power rails with a low leakage current requirement, and the off-chip capacitor in the IC package is the only source of ESD protection for the IC die.

The off-chip capacitor can be on-package or on an interposer. The off-chip capacitor can be, as examples, an on-package capacitor (e.g., a ceramic or deep trench capacitor) or a passive capacitor or capacitive structure in an interposer (e.g., a metal-insulator-metal (MiM) capacitor or other capacitive structure in an active or passive interposer). The off-chip capacitor can be a passive component mounted on an IC package or interposer, or the off-chip capacitor can be in an interposer. In an interposer, the off-chip capacitor can be made in the interposer layers in addition to a discrete capacitor. The off-chip capacitor can be a discrete capacitor that is part of the RLC model and that is made of ceramic or any other material. The off-chip capacitor has a low leakage of electrical current, and therefore, the off-chip capacitor can be coupled to power supply rails that require ESD protection having low leakage current. The location of the RLC on the IC package should be near the location of a conductive ball that couples the IC package to a circuit board to minimize the ball-to-capacitor resistance and inductance.

The circuit system, such as an IC package, includes routing conductors that are part of the power supply rail. The routing conductors in the power supply rail couple together a conductive ball external to the circuit system, the off-chip capacitor, and the IC die. The routing conductors in the power supply rail can be arranged to maintain low inductance to the off-chip capacitor, so that the capacitor can provide effective ESD protection to the power supply rail of the IC die. The off-chip capacitor can be coupled to a power supply rail for an IC die that has insufficient on-package decoupling (OPD) capacitance or insufficient on-die capacitance (ODC) to provide ESD protection. The routing conductors in the circuit system for the power supply rail and the conductive ball assignment can be optimized to minimize the inductance between the conductive ball and the off-chip capacitor for effective ESD protection. There does not need to be any special restriction on the routing conductors between the off-chip capacitor and the IC die to be protected from ESD.

According to some examples disclosed herein, the area used by the off-chip capacitor is small (e.g., less than 1% of the area of an interposer), making the off-chip capacitor a cost effective solution for many circuit systems. The off-chip capacitor can be placed close to the conductive ball coupled to the circuit system. The off-chip capacitor can, as a specific example that is not intended to be limiting, have a capacitance of 50 nanofarads (nF) and satisfy a CDM specification of 250 volts and an HBM specification of 1 kV. According to another specific example, the off-chip capacitor can have a low leakage current of less than 200 nA. The off-chip capacitor can be coupled to a power supply rail that does not require a capacitor to reduce supply voltage droop resulting from high dl/dt events.

One or more specific examples are described below. In an effort to provide a concise description of these examples, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Throughout the specification, and in the claims, the terms “connected” and “connection” mean a direct electrical connection between the circuits that are connected, without any intermediary devices. The terms “coupled” and “coupling” mean either a direct electrical connection between circuits or an indirect electrical connection through one or more passive or active intermediary devices that allows the transfer of information between circuits. The term “circuit” may mean one or more passive and/or active electrical components that are arranged to cooperate with one another to provide a desired function.

This disclosure discusses integrated circuit devices, including configurable (programmable) integrated circuits, such as field programmable gate arrays (FPGAs) and programmable logic devices. As discussed herein, an integrated circuit (IC) can include hard logic and/or soft logic. The circuits in an integrated circuit device (e.g., in a configurable IC) that are configurable by an end user are referred to as “soft logic.” “Hard logic” generally refers to circuits in an integrated circuit device that have substantially less configurable features than soft logic or no configurable features.

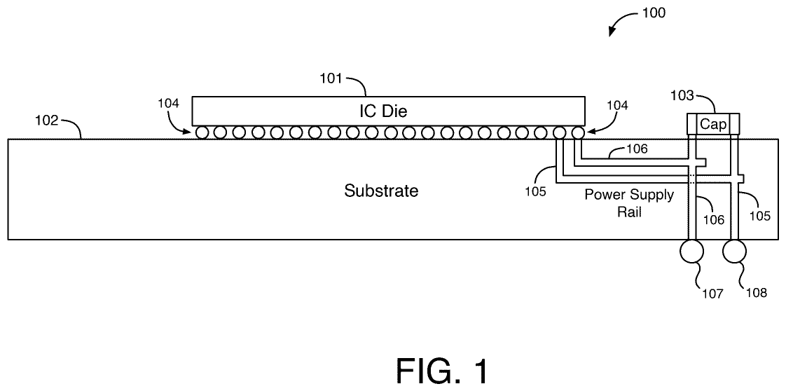

FIG. 1 is a diagram that illustrates an example of a circuit system 100 that includes an off-chip capacitor 103 that provides electrostatic discharge (ESD) protection to an integrated circuit (IC) die 101 in the circuit system 100. The circuit system 100 of FIG. 1 includes IC die 101, substrate 102, off-chip capacitor 103, conductive microbumps 104, and conductive balls 107-108. According to a specific example, circuit system 100 can be an integrated circuit (IC) package, and substrate 102 can be a package substrate of the IC package. According to another example, circuit system 100 can be an IC package, and the substrate 102 can be an active interposer or a passive interposer in the IC package. Substrate 102 is also referred to herein as an electronic device. IC die 101 can be any type of integrated circuit, such as a configurable IC (e.g., a field programmable gate array (FPGA) or programmable logic device (PLD)), a microprocessor IC, a graphics processing unit (GPU) IC, a memory IC, an application specific IC, a transceiver IC, etc.

Substrate 102 includes first external terminals (e.g., external conductive pads) that are coupled to microbumps 104. IC die 101 is coupled to conductors in substrate 102 through the conductive microbumps 104 and the first external terminals of substrate 102. Substrate 102 includes second external terminals (e.g., external conductive pads) that are coupled to conductive balls. Substrate 102 is coupled to a circuit board (not shown) through the second external terminals and the conductive balls, including conductive balls 107-108. Substrate 102 includes two conductors 105 and 106 (e.g., made of metal or metal alloy) that are part of a power supply rail. Conductor 105 is routed behind conductor 106 as shown by dotted lines in FIG. 1. Each of the conductors 105 and 106 includes two conductive portions routed vertically and a conductive portion routed horizontally as shown in FIG. 1.

The power supply rail includes conductors 105-106. The power supply rail provides power from the circuit board through conductive balls 107-108, two of the second external terminals, conductors 105-106, two of the first external terminals, and two of the microbumps 104 to circuitry in IC die 101. As an example, conductor 105 can route a supply voltage to IC die 101, and conductor 106 can route a ground voltage to IC die 101. As another example, conductor 106 can route a supply voltage to IC die 101, and conductor 105 can route a ground voltage to IC die 101.

The capacitor 103 is mounted on top of the substrate 102 as shown in FIG. 1. Capacitor 103 is coupled to the conductors 105-106 in substrate 102 through conductive connections and through third external terminals (e.g., external conductive pads) of substrate 102. The first, second, and third external terminals of substrate 102 are also referred to herein as external ports. The capacitor 103 can be, for example, an on-package capacitor (OPC), if the circuit system 100 is an IC package. Capacitor 103 has two plates (or surfaces). Each of the plates of capacitor 103 is coupled to one of the conductors 105 or 106. Thus, a first plate of capacitor 103 is coupled to conductor 105, and a second plate of capacitor 103 is coupled to conductor 106. Through these couplings, capacitor 103 is coupled to the power supply rail that provides power to IC die 101.

The capacitor 103 protects IC die 101 and the power supply rail from electrostatic discharge (ESD) events. The capacitor 103 absorbs ESD charge injected from outside the circuit system 100 to the power supply rail through conductive balls 107-108, and as a result, the capacitor 103 protects the power supply rail and IC die 101 from damage caused by excessive voltage overshoot. Because capacitor 103 is outside of IC die 101 (i.e., an off-chip capacitor), capacitor 103 does not require die area in IC die 101, and therefore, capacitor 103 does not affect the cost or dimensions of IC die 101.

The capacitor 103 has a low leakage of electric current. As examples, the capacitor 103 can be a ceramic or deep trench capacitor. Therefore, the capacitor 103 can be used in circuit system 100 if the power supply rail that includes conductors 105-106 requires ESD protection having a low leakage of electric current.

The conductors 105-106 in the circuit system 100 and the assignment of the conductive balls 107-108 can be optimized to minimize the inductance between the conductive balls 107-108 and the capacitor 103 for effective ESD protection. Circuit system 100 does not have any special restriction on routing the conductors 105-106 through substrate 102 between the capacitor 103 and the IC die 101.

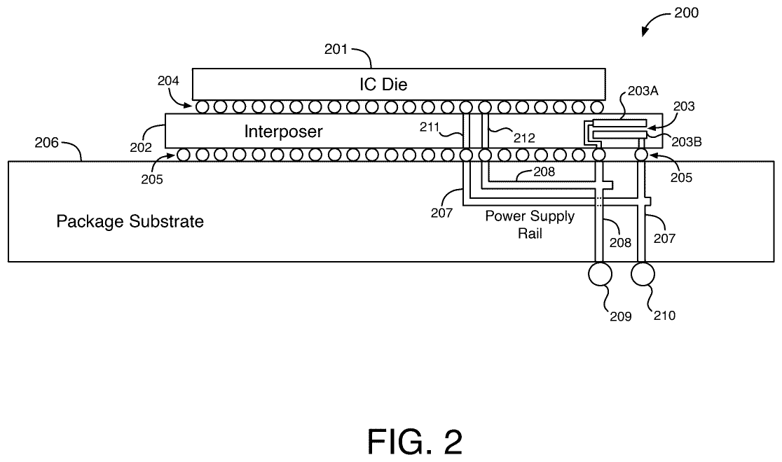

FIG. 2 is a diagram that illustrates an example of an integrated circuit (IC) package 200 that includes a capacitor 203 in an interposer 202 that provides electrostatic discharge (ESD) protection to an integrated circuit (IC) die 201 in the IC package 200. The IC package 200 of FIG. 2 includes the IC die 201, the interposer 202, a package substrate 206, conductive microbumps 204, conductive microbumps 205, and conductive balls 209-210. The interposer 202 includes an embedded capacitor 203. Capacitor 203 is an off-chip capacitor relative to IC die 201. Interposer 202 can be an active interposer or a passive interposer in the IC package 200. IC die 201 can be any type of integrated circuit, such as a configurable IC (e.g., a field programmable gate array (FPGA) or programmable logic device (PLD)), a microprocessor IC, a graphics processing unit IC, a memory IC, an application specific IC, a transceiver IC, etc.

IC die 201 is coupled to conductors in interposer 202 through the conductive microbumps 204. The conductors in interposer 202 are coupled to conductors in the package substrate 206 through conductive microbumps 205 and through first external terminals of package substrate 206. The package substrate 206 is coupled to a circuit board (not shown) through second external terminals of package substrate 206 and conductive balls, including conductive balls 209-210. Package substrate 206 includes two conductors 207 and 208 (e.g., made of metal or metal alloy) that are part of a power supply rail. Conductor 207 is routed behind conductor 208, as shown by dotted lines in FIG. 2. Each of the conductors 207 and 208 includes two conductive portions routed vertically and a conductive portion routed horizontally as shown in FIG. 2. Package substrate 206 is also referred to herein as an electronic device.

The power supply rail includes conductors 207-208. The power supply rail provides power from the circuit board through conductive balls 209-210, two of the second external terminals of substrate 206, conductors 207-208, two of the first external terminals of substrate 206, two of the microbumps 205, conductors 211-212 in interposer 202, and two of the microbumps 204 to circuitry in IC die 201. As an example, conductor 207 can route a supply voltage to IC die 201, and conductor 208 can route a ground voltage to IC die 201. As another example, conductor 208 can route a supply voltage to IC die 201, and conductor 207 can route a ground voltage to IC die 201.

The capacitor 203 is formed in layers of the interposer 202 as shown in FIG. 2. Thus, the capacitor 203 is embedded in interposer 202. Capacitor 203 is coupled to the package substrate 206 through two of microbumps 205 and two of third external terminals of package substrate 206. Capacitor 203 has two conductive plates (or surfaces) 203A and 203B. Each of the plates 203A and 203B of capacitor 203 is coupled to one of the conductors 207 or 208 in package substrate 206. The first plate 203A of capacitor 203 is coupled to conductor 208, and the second plate 203B of capacitor 203 is coupled to conductor 207. Through these couplings, the capacitor 203 is coupled to the power supply rail that provides power to IC die 201.

The capacitor 203 protects IC die 201 and the power supply rail from electrostatic discharge (ESD) events. The capacitor 203 absorbs ESD charge injected from outside the IC package 200 to the power supply rail through conductive balls 209-210, and as a result, the capacitor 203 protects the power supply rail and IC die 201 from damage caused by excessive voltage overshoot. Because capacitor 203 is outside of IC die 201, capacitor 203 does not require die area in IC die 203, and therefore, capacitor 203 does not affect the cost or dimensions of IC die 201.

The capacitor 203 has a low leakage of electric current. As an example, the capacitor 203 can be a metal-insulator-metal (MiM) capacitor. Therefore, capacitor 203 can be used in a circuit system, such as IC package 200, having a power supply rail that requires ESD protection having a low leakage of electric current.

The conductors 207-208 in IC package 200 and the assignment of the conductive balls 209-210 can be optimized to minimize the inductance between the conductive balls 209-210 and the capacitor 203 for effective ESD protection. IC package 200 does not have any special restriction on routing the conductors 207-208 through package substrate 206 between the capacitor 203 and the conductors 211-212.

According to some examples, the off-chip capacitance provided for ESD protection of the IC die and the resistance and the inductance in the power supply rail are placed closer to the conductive balls to reduce voltage overshoot at the IC die and the package nodes during an ESD event, such as a 250 volt charge device model (CDM) event. If the off-chip capacitance and the resistance and the inductance in the power supply rail are placed too close to a node in the substrate near the IC die, the substrate node near the IC die may experience voltage overshoot during an ESD event.

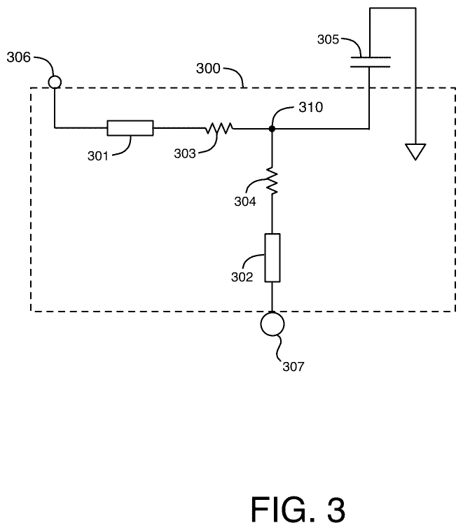

FIG. 3 is a schematic diagram that illustrates an example of a portion of a power supply rail in a substrate that provides power to an integrated circuit (IC) die. FIG. 3 depicts a substrate 300 that includes the portion of the power supply rail. Substrate 300 can be, as examples, substrate 102 of FIG. 1 or package substrate 206 of FIG. 2. The portion of the power supply rail within the substrate 300 of FIG. 3 includes conductors that have inductances 301 and 302 and resistances 303 and 304. These inductances and resistances are part of the conductors in the power supply rail. The conductors within the substrate 300 are depicted as lines in FIG. 3. The inductances 301 and 302 and resistances 303 and 304 are parasitic inductances and resistances, respectively, in the conductors in the power supply rail. Capacitor 305 is an off-chip capacitor that provides ESD protection to an integrated circuit die during ESD events. Capacitor 305 can be, as examples, capacitor 103 of FIG. 1 or capacitor 203 of FIG. 2.

The power supply rail within substrate 300 is coupled to conductive microbump 306 and to conductive ball 307. Conductive microbump 306 can be an example of one of conductive microbumps 104 or 205. Conductive ball 307 can be an example of one of conductive balls 107-108 or 209-210.

As shown in FIG. 3, inductance 301 is located between conductive microbump 306 and resistance 303. Resistance 303 is located between inductance 301 and a node 310 in the power supply rail that is coupled to resistance 304 and capacitor 305. Capacitor 305 is located outside substrate 300 between node 310 and a ground node at a ground voltage (e.g., one conductor of the power supply rail). Resistance 304 is located between node 310 and inductance 302. Inductance 302 is located between resistance 304 and conductive ball 307.

In the example of FIG. 3, the capacitor 305 and the conductor in the power supply rail in package 300 that includes resistance 304 and inductance 302 are placed close to the conductive ball 307 (i.e., coupled on the right side of inductance 301 and resistance 303 in FIG. 3) to reduce voltage overshoot at the IC die (e.g., at conductive microbump 306) and at the package nodes (e.g., node 310) during an ESD event, such as a 250 volt CDM event. If the conductor that includes resistance 304 and inductance 302 in the power supply rail is connected directly between microbump 306 and conductive ball 307, the microbump 306 near the IC die may experience voltage overshoot during an ESD event.

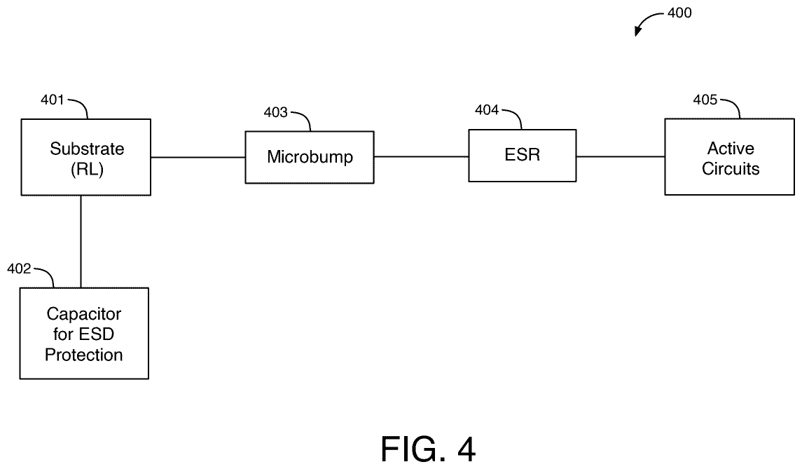

FIG. 4 is a diagram that illustrates an example of a circuit system 400 that includes a power supply rail for providing power to an IC die in the circuit system 400. The circuit system 400 of FIG. 4 includes a substrate 401 having a power supply rail that includes conductors, a capacitor 402, a microbump 403, equivalent series resistance (ESR) 404, and active circuits 405 in an integrated circuit (IC) die. The conductors in the power supply rail in substrate 401 have resistance and inductance (RL), as described above with respect to FIG. 3. The capacitor 402 is coupled to the conductors in the power supply rail in substrate 401. The capacitor 402 provides ESD protection for active circuits 405 during ESD events, as disclosed herein, for example, with respect to FIGS. 1-3. The capacitor 402 can be, as examples, a capacitor in an interposer, such as capacitor 203 of FIG. 2, or a capacitor that is external to, and coupled to, substrate 401 (e.g., a package substrate or interposer), such as capacitor 103 of FIG. 1.

The microbump 403 can be, as examples, one of conductive microbumps 104 or 205. ESR 404 can be in an interposer or in the IC die. Power flows from an external source through the power supply rail in substrate 401, microbump 403, and ESR 404 to the active circuits 405 in the IC die to power the active circuits 405. The capacitor 402 provides protection during ESD events for the power supply rail and for the active circuits 405. The capacitor 402 has a low leakage current as described above. As an example, a CDM event of 6 Amperes can be successfully handled by the circuit system 400 of FIG. 4 to keep the voltages at the microbump 403 and at nodes in substrate 401 from reaching maximum voltage limits.

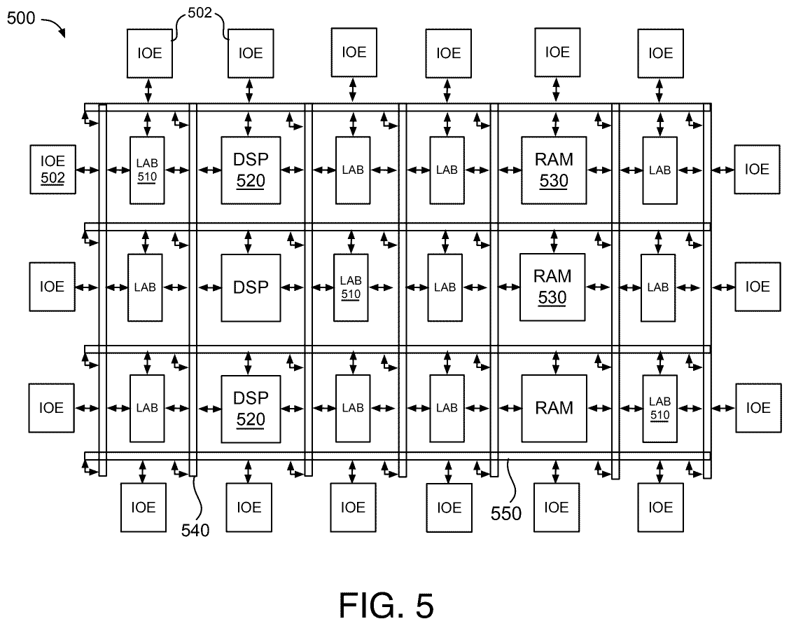

FIG. 5 illustrates an example of a configurable logic integrated circuit (IC) 500 that can be, for example, any of the IC dies disclosed herein with respect to any, some, or all of FIGS. 1, 2, 3, and/or 4 (e.g., IC die 101 or 201). As shown in FIG. 5, the configurable logic integrated circuit (IC) 500 includes a two-dimensional array of configurable functional circuit blocks, including configurable logic array blocks (LABs) 510 and other functional circuit blocks, such as random access memory (RAM) blocks 530 and digital signal processing (DSP) blocks 520. Functional blocks such as LABs 510 can include smaller programmable logic circuits (e.g., logic elements, logic blocks, or adaptive logic modules) that receive input signals and perform custom functions on the input signals to produce output signals.

In addition, programmable logic IC 500 can have input/output elements (IOEs) 502 for driving signals off of programmable logic IC 500 and for receiving signals from other devices. Input/output elements 502 can include parallel input/output circuitry, serial data transceiver circuitry, differential receiver and transmitter circuitry, or other circuitry used to connect one integrated circuit to another integrated circuit. As shown, input/output elements 502 can be located around the periphery of the chip. If desired, the programmable logic IC 500 can have input/output elements 502 arranged in different ways. For example, input/output elements 502 can form one or more columns, rows, or islands of input/output elements that may be located anywhere on the programmable logic IC 500.

The programmable logic IC 500 can also include programmable interconnect circuitry in the form of vertical routing channels 540 (i.e., interconnects formed along a vertical axis of programmable logic IC 500) and horizontal routing channels 550 (i.e., interconnects formed along a horizontal axis of programmable logic IC 500), each routing channel including at least one conductor to route at least one signal.

Note that other routing topologies, besides the topology of the interconnect circuitry depicted in FIG. 5, may be used. For example, the routing topology can include wires that travel diagonally or that travel horizontally and vertically along different parts of their extent as well as wires that are perpendicular to the device plane in the case of three dimensional integrated circuits. The driver of a wire can be located at a different point than one end of a wire.

Furthermore, it should be understood that embodiments disclosed herein with respect to FIGS. 1-4 can be implemented in any integrated circuit or electronic system. If desired, the functional blocks of such an integrated circuit can be arranged in more levels or layers in which multiple functional blocks are interconnected to form still larger blocks. Other device arrangements can use functional blocks that are not arranged in rows and columns.

Programmable logic IC 500 can contain programmable memory elements. Memory elements can be loaded with configuration data using input/output elements (IOEs) 502. Once loaded, the memory elements each provide a corresponding static control signal that controls the operation of an associated configurable functional block (e.g., LABs 510, DSP blocks 520, RAM blocks 530, or input/output elements 502).

In a typical scenario, the outputs of the loaded memory elements are applied to the gates of metal-oxide-semiconductor field-effect transistors (MOSFETs) in a functional block to turn certain transistors on or off and thereby configure the logic in the functional block including the routing paths. Programmable logic circuit elements that can be controlled in this way include multiplexers (e.g., multiplexers used for forming routing paths in interconnect circuits), look-up tables, logic arrays, AND, OR, XOR, NAND, and NOR logic gates, pass gates, etc.

The programmable memory elements can be organized in a configuration memory array having rows and columns. A data register that spans across all columns and an address register that spans across all rows can receive configuration data. The configuration data can be shifted onto the data register. When the appropriate address register is asserted, the data register writes the configuration data to the configuration memory bits of the row that was designated by the address register.

In certain embodiments, programmable logic IC 500 can include configuration memory that is organized in sectors, whereby a sector can include the configuration RAM bits that specify the functions and/or interconnections of the subcomponents and wires in or crossing that sector. Each sector can include separate data and address registers.

The configurable logic IC of FIG. 5 is merely one example of an IC that can be used with embodiments disclosed herein. The embodiments disclosed herein can be used with any suitable integrated circuit or system. For example, the embodiments disclosed herein can be used with numerous types of devices such as processor integrated circuits, central processing units, memory integrated circuits, graphics processing unit integrated circuits, application specific standard products (ASSPs), application specific integrated circuits (ASICs), and programmable logic integrated circuits. Examples of programmable logic integrated circuits include programmable arrays logic (PALs), programmable logic arrays (PLAs), field programmable logic arrays (FPLAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The integrated circuits disclosed in one or more embodiments herein can be part of a data processing system that includes one or more of the following components: a processor; memory; input/output circuitry; and peripheral devices. The data processing system can be used in a wide variety of applications, such as computer networking, data networking, instrumentation, video processing, digital signal processing, or any suitable other application. The integrated circuits can be used to perform a variety of different logic functions.

In general, software and data for performing any of the functions disclosed herein can be stored in non-transitory computer readable storage media. Non-transitory computer readable storage media is tangible computer readable storage media that stores data and software for access at a later time, as opposed to media that only transmits propagating electrical signals (e.g., wires). The software code may sometimes be referred to as software, data, program instructions, instructions, or code. The non-transitory computer readable storage media can, for example, include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

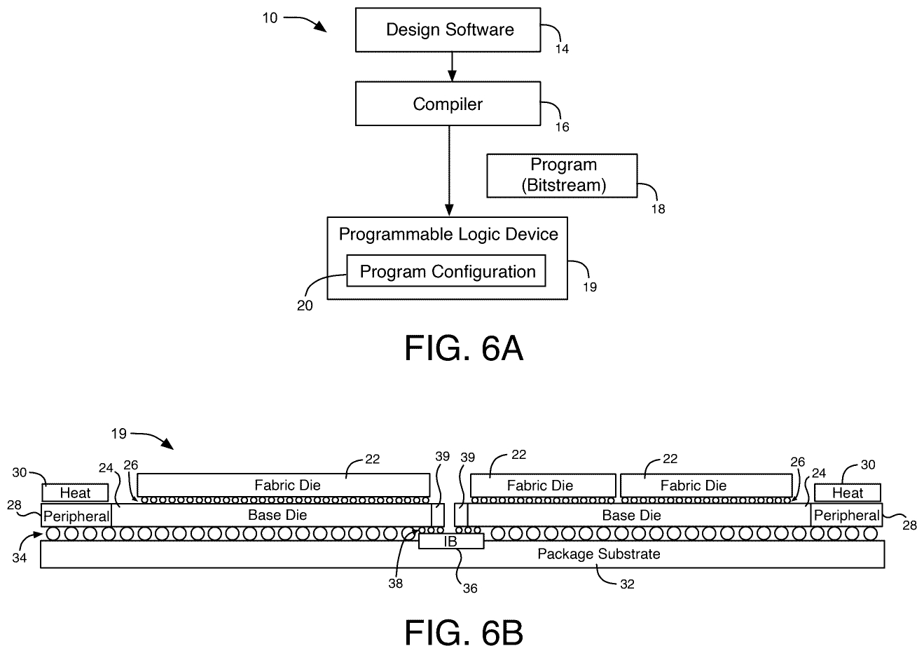

FIG. 6A illustrates a block diagram of a system 10 that can be used to implement a circuit design to be programmed into a programmable logic device 19 using design software. A designer can implement circuit design functionality on an integrated circuit, such as a reconfigurable programmable logic device 19 (e.g., a field programmable gate array (FPGA)). The designer can implement the circuit design to be programmed onto the programmable logic device 19 using design software 14. The design software 14 can use a compiler 16 to generate a low-level circuit-design program (bitstream) 18, sometimes known as a program object file and/or configuration program, that programs the programmable logic device 19. Thus, the compiler 16 can provide machine-readable instructions representative of the circuit design to the programmable logic device 19. For example, the programmable logic device 19 can receive one or more programs (bitstreams) 18 that describe the hardware implementations that should be stored in the programmable logic device 19. A program (bitstream) 18 can be programmed into the programmable logic device 19 as a configuration program 20. The configuration program 20 can, in some cases, represent an accelerator function to perform for machine learning, video processing, voice recognition, image recognition, or other highly specialized task.

In some implementations, a programmable logic device can be any integrated circuit device that includes a programmable logic device with two separate integrated circuit die where at least some of the programmable logic fabric is separated from at least some of the fabric support circuitry that operates the programmable logic fabric. One example of such a programmable logic device is shown in FIG. 6B, but many others can be used, and it should be understood that this disclosure is intended to encompass any suitable programmable logic device where programmable logic fabric and fabric support circuitry are at least partially separated on different integrated circuit die.

FIG. 6B is a diagram that depicts an example of the programmable logic device 19 that includes three fabric die 22 and two base die 24 that are connected to one another via microbumps 26. In the example of FIG. 6B, at least some of the programmable logic fabric of the programmable logic device 19 is in the three fabric die 22, and at least some of the fabric support circuitry that operates the programmable logic fabric is in the two base die 24. For example, some of the circuitry of configurable IC 500 shown in FIG. 5 (e.g., LABs 510, DSP 520, and RAM 530) can be located in the fabric die 22 and some of the circuitry of IC 500 (e.g., input/output elements 502) can be located in the base die 24.

Although the fabric die 22 and base die 24 appear in a one-to-one relationship or a two-to-one relationship in FIG. 6B, other relationships can be used. For example, a single base die 24 can attach to several fabric die 22, or several base die 24 can attach to a single fabric die 22, or several base die 24 can attach to several fabric die 22 (e.g., in an interleaved pattern). Peripheral circuitry 28 can be attached to, embedded within, and/or disposed on top of the base die 24, and heat spreaders 30 can be used to reduce an accumulation of heat on the programmable logic device 19. The heat spreaders 30 can appear above, as pictured, and/or below the package (e.g., as a double-sided heat sink). The base die 24 can attach to a package substrate 32 via conductive bumps 34. In the example of FIG. 6B, two pairs of fabric die 22 and base die 24 are shown communicatively connected to one another via an interconnect bridge 36 (e.g., an embedded multi-die interconnect bridge (EMIB)) and microbumps 38 at bridge interfaces 39 in base die 24.

In combination, the fabric die 22 and the base die 24 can operate in combination as a programmable logic device 19 such as a field programmable gate array (FPGA). It should be understood that an FPGA can, for example, represent the type of circuitry, and/or a logical arrangement, of a programmable logic device when both the fabric die 22 and the base die 24 operate in combination. Moreover, an FPGA is discussed herein for the purposes of this example, though it should be understood that any suitable type of programmable logic device can be used.

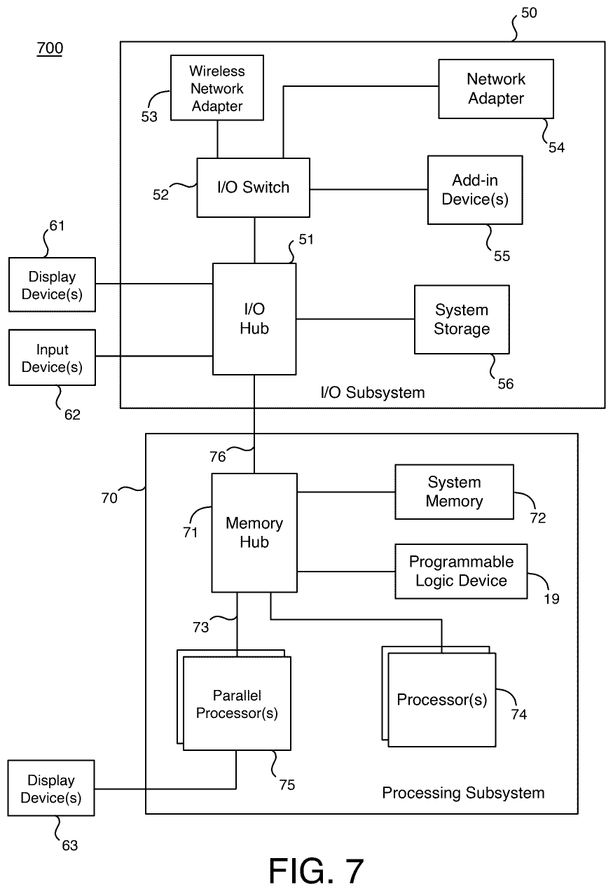

FIG. 7 is a block diagram illustrating a computing system 700 configured to implement one or more aspects of the embodiments described herein. The computing system 700 includes a processing subsystem 70 having one or more processor(s) 74, a system memory 72, and a programmable logic device 19 communicating via an interconnection path that can include a memory hub 71. The memory hub 71 can be a separate component within a chipset component or can be integrated within the one or more processor(s) 74. The memory hub 71 couples with an input/output (I/O) subsystem 50 via a communication link 76. The I/O subsystem 50 includes an input/output (I/O) hub 51 that can enable the computing system 700 to receive input from one or more input device(s) 62. Additionally, the I/O hub 51 can enable a display controller, which can be included in the one or more processor(s) 74, to provide outputs to one or more display device(s) 61. In one embodiment, the one or more display device(s) 61 coupled with the I/O hub 51 can include a local, internal, or embedded display device.

In one embodiment, the processing subsystem 70 includes one or more parallel processor(s) 75 coupled to memory hub 71 via a bus or other communication link 73. The communication link 73 can use one of any number of standards based communication link technologies or protocols, such as, but not limited to, PCI Express, or can be a vendor specific communications interface or communications fabric. In one embodiment, the one or more parallel processor(s) 75 form a computationally focused parallel or vector processing system that can include a large number of processing cores and/or processing clusters, such as a many integrated core (MIC) processor. In one embodiment, the one or more parallel processor(s) 75 form a graphics processing subsystem that can output pixels to one of the one or more display device(s) 61 coupled via the I/O Hub 51. The one or more parallel processor(s) 75 can also include a display controller and display interface (not shown) to enable a direct connection to one or more display device(s) 63.

Within the I/O subsystem 50, a system storage unit 56 can connect to the I/O hub 51 to provide a storage mechanism for the computing system 700. An I/O switch 52 can be used to provide an interface mechanism to enable connections between the I/O hub 51 and other components, such as a network adapter 54 and/or a wireless network adapter 53 that can be integrated into the platform, and various other devices that can be added via one or more add-in device(s) 55. The network adapter 54 can be an Ethernet adapter or another wired network adapter. The wireless network adapter 53 can include one or more of a Wi-Fi, Bluetooth, near field communication (NFC), or other network device that includes one or more wireless radios.

The computing system 700 can include other components not shown in FIG. 7, including other port connections, optical storage drives, video capture devices, and the like, that can also be connected to the I/O hub 51. Communication paths interconnecting the various components in FIG. 7 can be implemented using any suitable protocols, such as PCI (Peripheral Component Interconnect) based protocols (e.g., PCI-Express), or any other bus or point-to-point communication interfaces and/or protocol(s), such as the NV-Link high-speed interconnect, or interconnect protocols known in the art.

In one embodiment, the one or more parallel processor(s) 75 incorporate circuitry optimized for graphics and video processing, including, for example, video output circuitry, and constitutes a graphics processing unit (GPU). In another embodiment, the one or more parallel processor(s) 75 incorporate circuitry optimized for general purpose processing, while preserving the underlying computational architecture. In yet another embodiment, components of the computing system 700 can be integrated with one or more other system elements on a single integrated circuit. For example, the one or more parallel processor(s) 75, memory hub 71, processor(s) 74, and I/O hub 51 can be integrated into a system on chip (SoC) integrated circuit. Alternatively, the components of the computing system 700 can be integrated into a single package to form a system in package (SIP) configuration. In one embodiment, at least a portion of the components of the computing system 700 can be integrated into a multi-chip module (MCM), which can be interconnected with other multi-chip modules into a modular computing system.

The computing system 700 shown herein is illustrative. Other variations and modifications are also possible. The connection topology, including the number and arrangement of bridges, the number of processor(s) 74, and the number of parallel processor(s) 75, can be modified as desired. For instance, in some embodiments, system memory 72 is connected to the processor(s) 74 directly rather than through a bridge, while other devices communicate with system memory 72 via the memory hub 71 and the processor(s) 74. In other alternative topologies, the parallel processor(s) 75 are connected to the I/O hub 51 or directly to one of the one or more processor(s) 74, rather than to the memory hub 71. In other embodiments, the I/O hub 51 and memory hub 71 can be integrated into a single chip. Some embodiments can include two or more sets of processor(s) 74 attached via multiple sockets, which can couple with two or more instances of the parallel processor(s) 75.

Some of the particular components shown herein are optional and may not be included in all implementations of the computing system 700. For example, any number of add-in cards or peripherals can be supported, or some components can be eliminated. Furthermore, some architectures can use different terminology for components similar to those illustrated in FIG. 7. For example, the memory hub 71 can be referred to as a Northbridge in some architectures, while the I/O hub 51 can be referred to as a Southbridge.

Additional examples are now described. Example 1 is a circuit system comprising: an electronic device comprising a first external terminal, a second external terminal, a third external terminal, and a power supply rail coupled to the first external terminal, the second external terminal, and the third external terminal; and a capacitor coupled to the power supply rail in the electronic device through the third external terminal, wherein the capacitor is configured to provide voltage overshoot protection to an integrated circuit die coupled to the first external terminal of the electronic device during an electrostatic discharge event occurring in the power supply rail, and wherein the capacitor is external to the integrated circuit die.
In Example 2, the circuit system of Example 1, wherein the circuit system comprises an integrated circuit package, wherein the capacitor is an on-package capacitor, and wherein the electronic device comprises a package substrate.
In Example 3, the circuit system of any one of Examples 1-2, wherein the electronic device comprises an interposer, wherein the capacitor is external to the interposer, and wherein the capacitor is coupled to the interposer.
In Example 4, the circuit system of any one of Examples 1-3 further comprises an interposer coupled to the electronic device and to the integrated circuit die, wherein the capacitor is inside the interposer.
In Example 5, the circuit system of any one of Examples 1-4, wherein the capacitor is one of a ceramic capacitor, a deep trench capacitor, or a metal-insulator-metal (MiM) capacitor.
In Example 6, the circuit system of any one of Examples 1-5, wherein the capacitor is coupled to the first and the second external terminals of the electronic device through the third external terminal of the electronic device and through the power supply rail, and wherein the second external terminal of the electronic device is closer to the third external terminal of the electronic device than to the first external terminal of the electronic device.
In Example 7, the circuit system of any one of Examples 1-6, wherein the capacitor has a low leakage of electric current.
In Example 8, the circuit system of any one of Examples 1-7, wherein the power supply rail comprises conductors that are coupled to provide power to the integrated circuit die during operation of the integrated circuit die.
In Example 9, the circuit system of any one of Examples 1-8 further comprises an interposer coupled between the electronic device and the integrated circuit die, wherein the capacitor comprises layers in the interposer, wherein the circuit system is an integrated circuit package, and wherein the electronic device comprises a package substrate.
Example 10 is a method for protecting an integrated circuit die during an electrostatic discharge event affecting a conductor that provides a power supply in a circuit system, the method comprising: providing a substrate comprising a first external terminal, a second external terminal, a third external terminal, and the conductor that provides the power supply, wherein the conductor is coupled to the first, the second, and the third external terminals of the substrate, and wherein the integrated circuit die is coupled to the first external terminal; and providing a capacitor coupled to the conductor through the third external terminal of the substrate, wherein the capacitor is configured to provide voltage overshoot protection to the integrated circuit die during the electrostatic discharge event, and wherein the capacitor is external to the integrated circuit die.
In Example 11, the method of Example 10, wherein the circuit system comprises an integrated circuit package, wherein the capacitor is an on-package capacitor, and wherein the substrate comprises a package substrate.
In Example 12, the method of any one of Examples 10-11, wherein the substrate comprises an interposer, wherein the capacitor is external to the interposer, and wherein the capacitor is coupled to the interposer.
In Example 13, the method of any one of Examples 10-12 further comprises providing an interposer between the substrate and the integrated circuit die, wherein the capacitor is inside the interposer.
In Example 14, the method of any one of Examples 10-13 further comprises providing an interposer between the substrate and the integrated circuit die, wherein the capacitor comprises layers in the interposer, wherein the circuit system comprises an integrated circuit package, and wherein the substrate comprises a package substrate.
In Example 15, the method of any one of Examples 10-14, wherein the capacitor has a low leakage of electric current.
Example 16 is a circuit system comprising: a substrate comprising a first external port, a second external port, and a conductor that provides power supply to an integrated circuit die, wherein the conductor is coupled to the first external port and to the second external port; and a capacitance coupled to the conductor in the substrate through the second external port of the substrate, wherein the capacitance provides voltage overshoot protection to the integrated circuit die during an electrostatic discharge event in the conductor, wherein the capacitance is external to the integrated circuit die, and wherein the integrated circuit die is coupled to the first external port of the substrate.
In Example 17, the circuit system of Example 16, wherein the circuit system comprises an integrated circuit package, wherein the capacitance is an on-package capacitor, wherein the substrate comprises a package substrate, and wherein the capacitance has a low leakage of electric current.
In Example 18, the circuit system of any one of Examples 16-17, wherein the substrate comprises an interposer, wherein the capacitance is external to the interposer, and wherein the capacitance is coupled to the interposer.
In Example 19, the circuit system of any one of Examples 16-18 further comprises an interposer coupled between the substrate and the integrated circuit die, wherein the capacitance is inside the interposer.
In Example 20, the circuit system of any one of Examples 16-19 further comprises an interposer coupled between the substrate and the integrated circuit die, wherein the capacitance comprises layers in the interposer, wherein the circuit system is an integrated circuit package, and wherein the substrate is a package substrate.

The foregoing description of the exemplary embodiments has been presented for the purpose of illustration. The foregoing description is not intended to be exhaustive or to be limiting to the examples disclosed herein. The foregoing is merely illustrative of the principles of this disclosure and various modifications can be made by those skilled in the art. The foregoing embodiments may be implemented individually or in any combination.

What is claimed is:

1. A circuit system comprising:
an electronic device comprising a first external terminal, a second external terminal, a third external terminal, and a power supply rail that is coupled to the first external terminal, the second external terminal, and the third external terminal; and
a capacitor coupled to the power supply rail in the electronic device through the third external terminal, wherein the capacitor is configured to provide voltage overshoot protection to an integrated circuit die coupled to the first external terminal of the electronic device during an electrostatic discharge event occurring in the power supply rail, and wherein the capacitor is external to the integrated circuit die.

2. The circuit system of claim 1, wherein the circuit system comprises an integrated circuit package, wherein the capacitor is an on-package capacitor, and wherein the electronic device comprises a package substrate.

3. The circuit system of claim 1, wherein the electronic device comprises an interposer, wherein the capacitor is external to the interposer, and wherein the capacitor is coupled to the interposer.

4. The circuit system of claim 1 further comprising:
an interposer coupled to the electronic device and to the integrated circuit die, wherein the capacitor is inside the interposer.

5. The circuit system of claim 1, wherein the capacitor is one of a ceramic capacitor, a deep trench capacitor, or a metal-insulator-metal (MiM) capacitor.

6. The circuit system of claim 1, wherein the capacitor is coupled to the first and the second external terminals of the electronic device through the third external terminal of the electronic device and through the power supply rail, and wherein the second external terminal of the electronic device is closer to the third external terminal of the electronic device than to the first external terminal of the electronic device.

7. The circuit system of claim 1, wherein the capacitor has a low leakage of electric current.

8. The circuit system of claim 1, wherein the power supply rail comprises conductors that are coupled to provide power to the integrated circuit die during operation of the integrated circuit die.

9. The circuit system of claim 1 further comprising:
an interposer coupled between the electronic device and the integrated circuit die, wherein the capacitor comprises layers in the interposer, wherein the circuit system is an integrated circuit package, and wherein the electronic device comprises a package substrate.

10. A method for protecting an integrated circuit die during an electrostatic discharge event affecting a conductor that provides a power supply in a circuit system, the method comprising:
providing a substrate comprising a first external terminal, a second external terminal, a third external terminal, and the conductor that provides the power supply, wherein the conductor is coupled to the first, the second, and the third external terminals of the substrate, and wherein the integrated circuit die is coupled to the first external terminal; and
providing a capacitor coupled to the conductor through the third external terminal of the substrate, wherein the capacitor is configured to provide voltage overshoot protection to the integrated circuit die during the electrostatic discharge event, and wherein the capacitor is external to the integrated circuit die.

11. The method of claim 10, wherein the circuit system comprises an integrated circuit package, wherein the capacitor is an on-package capacitor, and wherein the substrate comprises a package substrate.

12. The method of claim 10, wherein the substrate comprises an interposer, wherein the capacitor is external to the interposer, and wherein the capacitor is coupled to the interposer.

13. The method of claim 10 further comprising:
providing an interposer between the substrate and the integrated circuit die, wherein the capacitor is inside the interposer.

14. The method of claim 10 further comprising:
providing an interposer between the substrate and the integrated circuit die, wherein the capacitor comprises layers in the interposer, wherein the circuit system comprises an integrated circuit package, and wherein the substrate comprises a package substrate.

15. The method of claim 10, wherein the capacitor has a low leakage of electric current.

16. A circuit system comprising:
a substrate comprising a first external port, a second external port, and a conductor that provides power supply to an integrated circuit die, wherein the conductor is coupled to the first external port and to the second external port; and
a capacitance coupled to the conductor in the substrate through the second external port of the substrate, wherein the capacitance provides voltage overshoot protection to the integrated circuit die during an electrostatic discharge event in the conductor, wherein the capacitance is external to the integrated circuit die, and wherein the integrated circuit die is coupled to the first external port of the substrate.

17. The circuit system of claim 16, wherein the circuit system comprises an integrated circuit package, wherein the capacitance is an on-package capacitor, wherein the substrate comprises a package substrate, and wherein the capacitance has a low leakage of electric current.

18. The circuit system of claim 16, wherein the substrate comprises an interposer, wherein the capacitance is external to the interposer, and wherein the capacitance is coupled to the interposer.

19. The circuit system of claim 16 further comprising:
an interposer coupled between the substrate and the integrated circuit die, wherein the capacitance is inside the interposer.

20. The circuit system of claim 16 further comprising:
an interposer coupled between the substrate and the integrated circuit die, wherein the capacitance comprises layers in the interposer, wherein the circuit system is an integrated circuit package, and wherein the substrate is a package substrate.
